(19) United States
(12) Patent Application Publication
(10) Pub. No.: US 2015/0049341 A1
(43) Pub. Date: Feb. 19, 2015

(54) METHOD FOR DRIVING LIGHT SOURCE APPARATUS AND SURFACE EMITTING LASER, AND IMAGE ACQUIRING APPARATUS

(71) Applicant: CANON KABUSHIKI KAISHA, TOKYO (JP)

(72) Inventors: Eiichi Fujii, Kamakura-shi (JP); Takeshi Uchida, Hiratsuka-shi (JP)

(21) Appl. No.: 14/458,615

(22) Filed: Aug. 13, 2014

(30) Foreign Application Priority Data
Aug. 19, 2013 (JP) 2013-169739
Jun. 26, 2014 (JP) 2014-131616

(51) Int. Cl. H01S 5/183; H01S 5/06; G01B 9/02; H01S 5/187

(52) U.S. Cl. CPC H01S 5/18361; H01S 5/187; H01S 5/0617; G01B 9/02091
USPC 356/479; 372/38.02

(57) ABSTRACT

A light source apparatus includes a surface emitting laser including a movable mirror, a mirror arranged opposite to the movable mirror, and an active layer arranged between the two mirrors, a mirror driving unit configured to move the movable mirror to a position where laser oscillation is not performed, a laser driving unit configured to inject current into the surface emitting laser, a storage unit configured to store position information of the movable mirror, the position information including a mirror position where laser oscillation is not performed and a mirror position where laser oscillation is performed, and a control unit configured to control the laser driving unit and to determine start timing of the current injection into the surface emitting laser according to the position information output from the storage unit.

### BACKGROUND OF THE INVENTION

1. Field of the Invention

The present invention relates to a method for driving a surface emitting laser and a light source apparatus including a surface emitting laser. The present invention also relates to an image acquiring apparatus including such a light source apparatus.

2. Description of the Related Art

Various types of light sources, in particular laser light sources, capable of allowing variable oscillation wavelengths have been used in the field of communication network and inspection equipment.

In the field of communication network, high speed wavelength switching may be desired, while high speed and wide range wavelength sweeping may be desired in the field of inspection equipment.

A variable wavelength (sweeping) light source may be used in the inspection equipment such as a laser spectroscope, a dispersion measuring device, a film thickness measuring apparatus, or a wavelength-swept type optical tomography (swept source optical coherence tomography which will be referred to as “SS-OCT” hereinafter) apparatus.

An SS-OCT apparatus is configured to acquire tomographic images of a sample using optical interference. Recently, this image acquiring technique has been increasingly popular for studies in the medical field, because of the capability of obtaining spatial resolution of micron order, noninvasive characteristic, etc.

As a wavelength-swept light source used in such an SS-OCT apparatus, a variable wavelength type surface emitting laser made by combining a surface emitting laser light source with a Micro Electro Mechanical Systems (MEMS) mirror has been focusing attention, since both high speed wavelength sweeping and a long interference distance, as well as a low manufacturing cost, can be achieved. Such a variable wavelength type surface emitting laser has been disclosed in Japanese Patent Application Laid-Open No. 2004-281733.

The surface emitting laser, however, may not emit a stable optical output when driven to light on and off repeatedly, and a desired output power cannot be obtained at the start of lighting. Accordingly, a wideband wavelength sweeping may not be performed in the variable wavelength type surface emitting laser.

This is because an internal temperature rise becomes significantly large when the surface emitting laser is driven. In addition, since the element characteristic is sensitive to temperature and the optical output may change with temperature even when the same current is injected, it is not possible to control the optical output during the startup only by the driving current.

### SUMMARY OF THE INVENTION

A light source apparatus according to an embodiment of the present invention includes a surface emitting laser including a movable mirror, a mirror arranged opposite to the movable mirror, and an active layer arranged between the two mirrors, a mirror driving unit configured to move the movable mirror to a position where laser oscillation is not performed, a laser driving unit configured to inject current into the surface emitting laser, a storage unit configured to store position information of the movable mirror, the position information including a mirror position where laser oscillation is not performed and a mirror position where laser oscillation is performed, and a control unit configured to control the laser driving unit and to determine start timing of the current injection into the surface emitting laser according to the position information output from the storage unit.

A method for driving a surface emitting laser according to an embodiment of the present invention is provided as a method for driving a surface emitting laser including a movable mirror, a mirror arranged opposite to the movable mirror, and an active layer arranged between the two mirrors, and the method includes starting current injection into the surface emitting laser after the movable mirror has moved to a position where a wavelength with no light emitting gain becomes a resonant wavelength in the surface emitting laser, and before the movable mirror is moved to a position where a wavelength with light emitting gain becomes the resonant wavelength in the surface emitting laser.

An image acquiring apparatus according to an embodiment of the present invention includes

the light source apparatus described above,

a sample measuring unit configured to irradiate a sample with light from the light source apparatus and transmit reflected light from the sample,

a reference unit configured to irradiate a reference mirror with light from the light source apparatus and transmit reflected light from the reference mirror,

an interference unit configured to interfere the reflected light from the sample measuring unit with the reflected light from the reference unit,

an optical detecting unit configured to detect interference light from the interference unit, and

an image processing unit configured to acquire an optical tomographic image of the sample according to the light detected by the optical detecting unit.

Further features of the present invention will become apparent from the following description of exemplary embodiments (with reference to the attached drawings).

### BRIEF DESCRIPTION OF THE DRAWINGS

FIG. 1 is an explanatory diagram illustrating an exemplary structure of a light source apparatus used in an OCT apparatus according to an embodiment of the present invention.

FIG. 2 is an explanatory view illustrating an exemplary light source according to the embodiment of the present invention.

FIG. 3 is a diagram for explaining a method for obtaining position information of a non-laser oscillating position of the mirror of Example 1 of the present invention.

FIG. 4 (includes FIG. 4A-FIG. 4D) is a diagram for explaining an operation of the light source apparatus of Example 1 of the present invention.

FIG. 5 (includes FIG. 5A-FIG. 5D) is a diagram for explaining Comparative Example 1.

FIG. 6 (includes FIG. 6A-FIG. 6D) is a diagram for explaining an exemplary structure of Example 2 of the present invention.

FIG. 7 is an explanatory diagram illustrating an exemplary structure of an image acquiring (OCT) apparatus with a light source apparatus according to Example 3 of the present invention.

### DESCRIPTION OF THE EMBODIMENTS

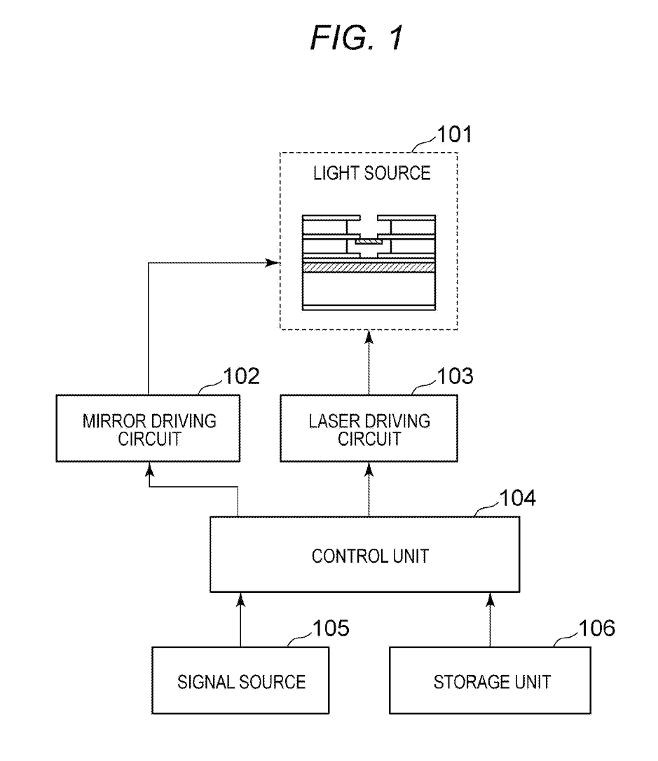

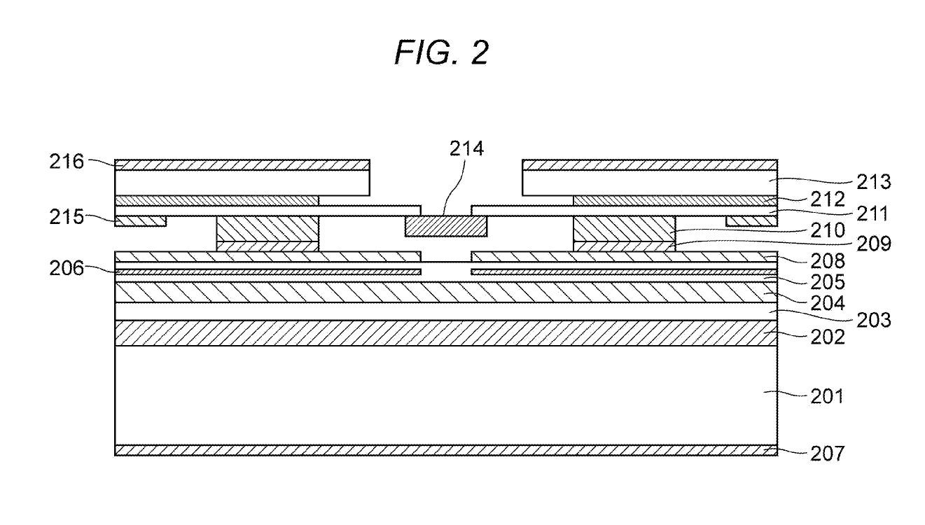

An exemplary structure of a light source apparatus used in an OCT apparatus (image acquiring apparatus) according to an embodiment of the present invention will be described below by referring to FIGS. 1, 2.

The light source apparatus includes a light source 101 which moves one of resonator mirrors of a vertical cavity surface emitting laser (VCSEL) by an MEMS.

The light source 101 of the present embodiment is implemented as a surface emitting laser configured to change a length of a resonator, which is formed by a movable mirror and a mirror arranged opposite to the movable mirror, to change the wavelength of laser light by a reciprocating movement of the movable mirror.

FIG. 2 illustrates a more detailed structure of the light source 101.

The light source 101 includes an electrically conductive semiconductor substrate 201, a lower distributed Bragg reflector (DBR) 202, an n-type clad layer 203, an active layer 204, a p-type clad layer 205, a current confinement layer 206, and laser driving electrodes 207, 208.

The light source 101 also includes an Si substrate 213, an insulating layer and movable gap forming layer 212, a movable beam 211, a movable mirror 214, an insulating layer and resonator gap forming layer 210, movable mirror driving electrodes 215, 216, and a gold pad 209 which is used to connect a light emitting portion and a movable mirror portion.

When a voltage is applied between the laser driving electrodes 207, 208, electrons or electron holes are injected from the electrodes 207, 208 to emit light by combination of electrons and electron holes in the active layer 204 which has the narrowest band gap. The light is amplified by an optical resonator, which is formed between the DBR 202 and the movable mirror 214, and ejected from the movable mirror 214 side.

In this case, a wavelength of the ejected laser light corresponds to the size of an air gap formed between the movable mirror 214 and the active layer 204. By changing the size of the air gap, therefore, the wavelength of the laser light can be changed.

Next, an operation to change the wavelength of the laser light will be described.

When a drive voltage is applied between the movable mirror driving electrodes 215, 216, electrostatic force acts between the movable beam 211 and the movable mirror driving electrode 216 to displace the movable mirror 214, which is provided on the movable beam 211, in a light ejecting direction, and the size of the air gap increases.

Thus, by controlling the drive voltage to adjust the size of the air gap, any laser light having a desired wavelength can be obtained.

To the light source 101, a mirror driving circuit (mirror driving unit) 102 configured to drive the MEMS mirror and a laser driving circuit (laser driving unit) 103 configured to drive the VCSEL are connected. The laser driving circuit 103 is a circuit from which an electric current is injected to the VCSEL.

The mirror driving circuit 102 and the laser driving circuit 103 are controlled by a control unit 104. The control unit 104 is synchronized with an output of a signal source 105 to generate a movable mirror driving signal by which the output light of the light source 101 changes in a nearly linear manner relative to a frequency.

The movable mirror 214 is driven at such an amplitude that the movable mirror 214 is moved to a position where the length of the laser resonator attains a wavelength at which the gain of the active layer is so small that the light source 101 cannot oscillate laser. The control unit 104 controls the laser driving circuit 103 by using position information of a storage unit 106 which stores the mirror position where no laser oscillation is performed, and determining current injection timing to the light source 101.

A method for determining the current injection timing to the light source 101 will be described in detail below.

First, the movable mirror is driven at a low speed of, for example, 0.1 Hz, while supplying, from the laser driving circuit, a direct current of a level similar to that used for the light source 101 for the OCT.

At this time, a relation between the position of the mirror and the output of the light source 101 is detected, and a position of the mirror where laser oscillation is performed and a position of the mirror where laser oscillation is not performed by the light source 101 are stored in the storage unit 106.

By using this information, a driving range of the movable mirror is determined so that the laser oscillation is not performed when the mirror is located at the shortest cavity position or the longest cavity position.

Accordingly, the movable mirror is driven within the determined range by the mirror driving circuit 102 in synchronism with the signal source 105.

Subsequently, at the time when the mirror is positioned closer to the active layer 204 side where the laser oscillation is not performed, relative to a mirror position where the length of the resonator becomes the shortest, the laser driving circuit 103 is controlled to start current injection into the light source.

Specifically, the current injection starts after the movable mirror has been moved to a position where a wavelength with no light emitting gain becomes the resonant wavelength of the surface emitting laser, and before the movable mirror is moved to a position where a wavelength with light emitting gain becomes the resonant wavelength of the surface emitting laser.

At this time, the time when the current injection starts may be at least 500 ns before the mirror is moved to reach the position where the laser oscillation is allowed. The time when the current injection starts may be more than 1 μs before the mirror is moved to reach the position where the laser oscillation is allowed.

Subsequently, the current injection into the light source 101 stops by controlling the laser driving circuit 103 when the mirror is positioned opposite to the active layer 204 side where the laser oscillation is not performed, relative to a mirror position where the length of the resonator becomes the longest.

Therefore, by controlling the mirror driving circuit 102 and the laser driving circuit 103 in this manner, a light source apparatus and a method for driving the same can be provided in the case of narrower width of the actual wavelength sweeping width, and performing a wide band wavelength sweeping from short wavelengths to long wavelengths.

In the case where such a variable wavelength type surface emitting laser is used in the SS-OCT apparatus, a quality of images may deteriorate when reciprocating sweeping is used to scan the eyeground to take an image thereof.

This is because the output is varied due to a nonlinear optical effect within the active layer, depending on whether the sweeping is performed from a short wavelength to a long wavelength, or from a long wavelength to a short wavelength.

Such an output variation affects tomographic images so that different levels of contrast are provided for each image taking point while the eyeground is scanned by reciprocating sweeping, and the quality of images would deteriorate.

To avoid this, an image taking method which only allows sweeping in a single direction has been adopted. When such an image taking method is used in an ophthalmologic SS-OCT apparatus, the light source would be kept turned off for about half the image taking time. This is to avoid unnecessary irradiation of laser light in the eyes to mostly prevent probable damages to the eyes due to the irradiation of laser light.

If, for example, tomographic images are taken at a scan rate of 100 kHz with the ophthalmologic SS-OCT apparatus, the light source is supposed to be kept turned off for about 5 μs.

Since a time constant of temperature change of the surface emitting laser is in the order of sub μs to several μs, the turn-off time mentioned above is sufficiently long to cause a change in oscillation threshold current by the internal temperature change. Therefore, when the image taking method using the wavelength sweeping in a single direction is used in the wavelength-swept type surface emitting laser, the oscillation threshold current of the surface emitting laser decreases with time at an output start portion of the wavelength-swept optical output, and the problem mentioned above would appear more apparently.

### EXAMPLES

Examples of the present invention will be described blow.

### Example 1

In Example 1, a light source apparatus for the OCT according to the embodiment of the present invention was constituted by an MEMS-VCSEL type light source which was capable of oscillating laser in the vicinity of 1,060 nm, and used a GaAs substrate and an active layer made of an InGaAs multiple quantum well.

To the light source 101, a constant current of 6 mA was supplied using the laser driving circuit 103. In this state, a movable mirror driving voltage to be applied from the mirror driving circuit was made to 0 V, and the movable mirror was held at a position zs where the shortest resonator length of the movable mirror was attained.

Next, the movable mirror driving voltage was gradually increased to move the movable mirror in a direction to increase the resonator length. In about ten seconds, the movable mirror was moved to a position ze where the longest resonator length was attained.

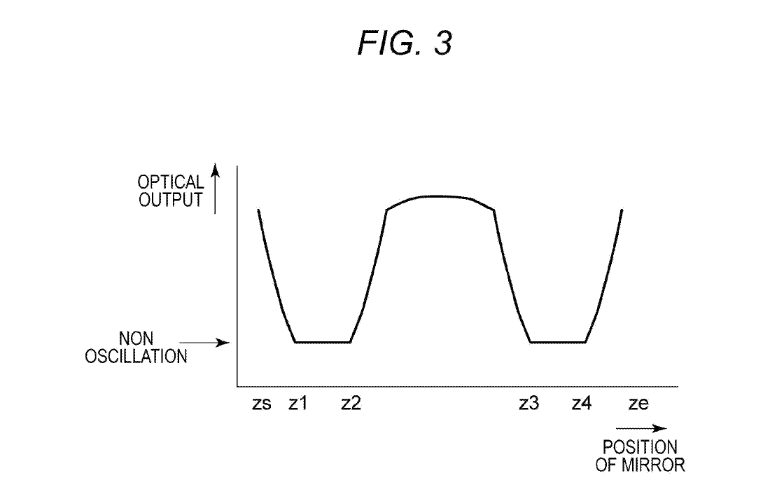

Meanwhile, a relation between the position of the mirror and the optical output was measured as illustrated in FIG. 3, and the mirror positions between positions z1 and z2 and between positions z3 and z4 were determined as non-laser oscillation positions.

The position information, as determined above, of the mirror positions where no laser oscillation was performed was stored in the storage unit 106. By using the position information stored in the storage unit 106, the mirror driving circuit was controlled by the control unit 104 in such a manner that the movable mirror became reciprocating between the positions z1 and z3. No laser oscillation occurred while the movable mirror was located between the positions z1 and z2.

A frequency, that is, a wavelength sweeping frequency, at which the movable mirror was reciprocating, was set to 100 kHz. At this time, the movable mirror was controlled to be driven in such a manner that a resonance frequency of the laser resonator generally changed in proportion to time. Meanwhile, the laser driving circuit was controlled as described below. Specifically, while the movable mirror was moved in a direction to decrease the length of the laser resonator, that is, in the course of moving the movable mirror from the position z3 to the position z1, current application of the laser driving current started when the movable mirror passed the position z2. While the movable mirror was moved in a direction to increase the length of the laser resonator, that is, in the course of moving the movable mirror from the position z1 to the position z3, the current application of the laser driving current then stopped when the movable mirror reached the position z3.

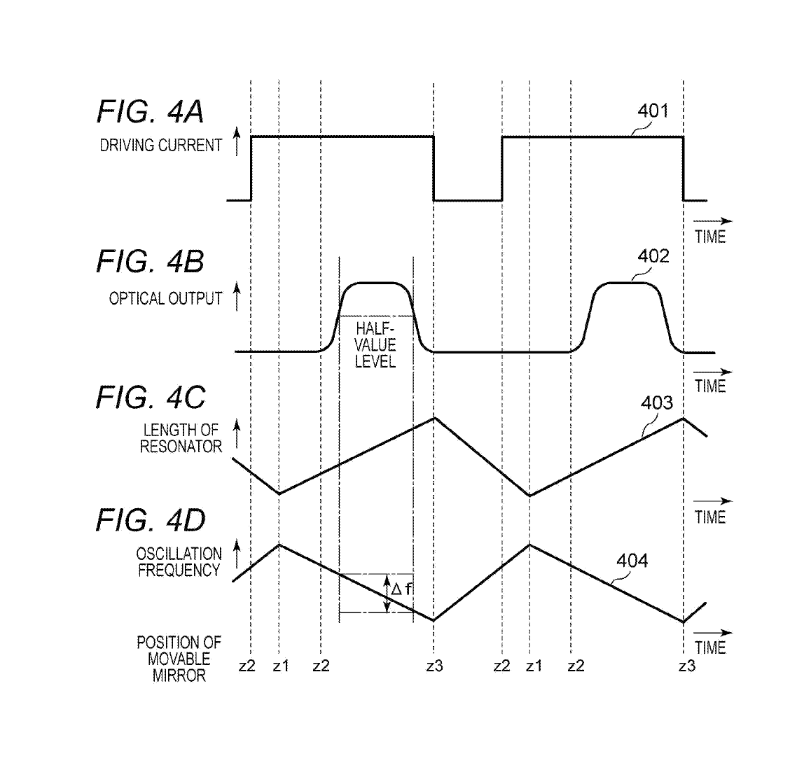

Next, an operation including a driving method for the light source apparatus of Example 1 above will be described by referring to FIG. 4A to FIG. 4D. FIG. 4A represents time change of the driving current, FIG. 4B represents changes of the optical output, FIG. 4C represents changes of the resonator length, and FIG. 4D represents changes of the laser oscillation frequency. In the light source apparatus of this example, it was controlled that time for preliminary current injection, during which no laser oscillation occurred even with the injection of the driving current, before the actual start of the optical output of the wavelength-swept light, was maximized.

On such a condition that no laser oscillation was performed, however, a temperature of the active layer in the resonator similarly increased in response to the current application, and the active layer was sufficiently pre-heated by such a preliminary injection before the start of the laser oscillation. As a result, sweeping over a wide band of 30 THz was realized at a half-value width of wavelength (Δf in FIG. 4D).

### Comparative Example

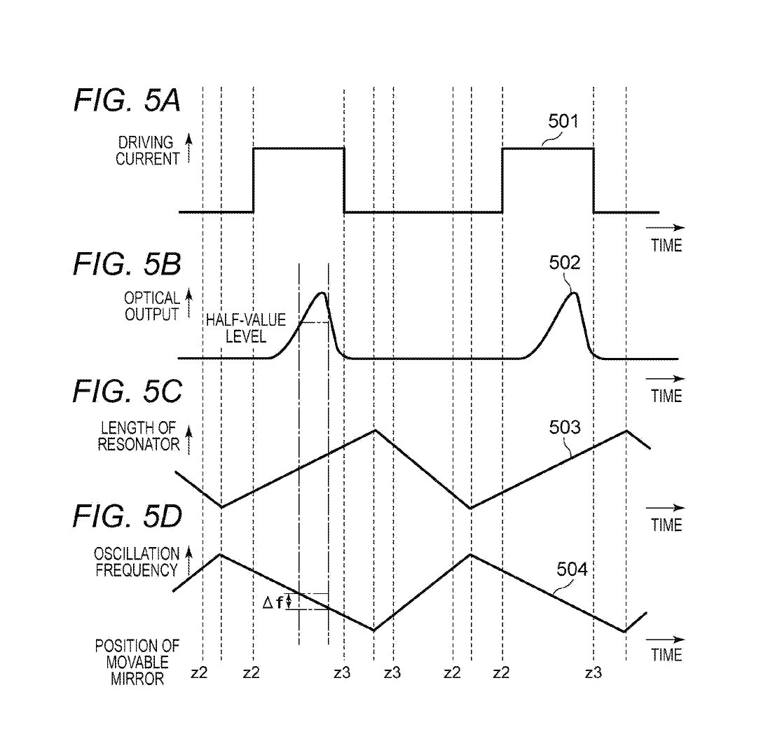

Next, Comparative Example will be described below by referring to FIG. 5A to FIG. 5D. FIG. 5A represents time change of the driving current, FIG. 5B represents changes of the optical output, FIG. 5C represents changes of the resonator length, and FIG. 5D represents changes of the laser oscillation frequency.

A light source similar to that of Example 1 was used to drive the movable mirror to cover the positions of the movable mirror between z2 and z3 where the laser oscillation was allowed by the light source as illustrated in FIG. 5A to FIG. 5D.

The laser driving circuit was operated to inject a laser driving current in an area where the movable mirror was moving in a direction to increase the length of the resonator and while the movable mirror was moved from the positions z2 to z3 where the laser oscillation was allowed.

Specifically, as usually performed in the art, the current injection started when it was desired to eject the laser light output, and the current injection stopped when it was desired to stop the laser light output.

As a result, as illustrated in FIG. 5B, the optical output decreased in the vicinity of the position z2, and only a small output was obtained on the high frequency (short wavelength) side.

The resulting half-value width of wavelength (Of in FIG. 5D) of the wavelength-swept output was 12 THz which provided only a wavelength-swept output of a narrower band, when compared to Example 1.

### Example 2

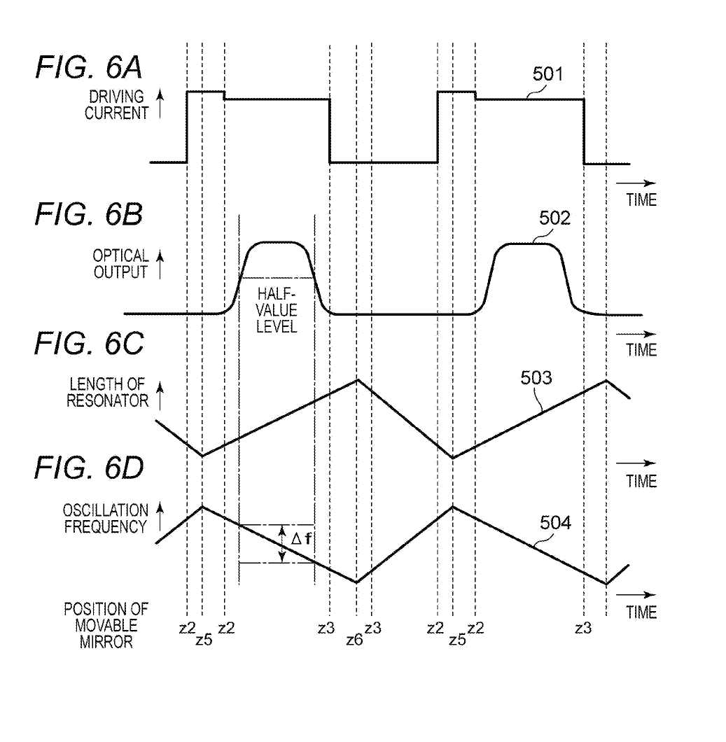

As Example 2, a light source apparatus for the OCT was constituted similarly to Example 1 as illustrated in FIG. 1 according to the embodiment of the present invention. FIG. 6A represents time change of the driving current, FIG. 6B represents changes of the optical output, FIG. 6C represents changes of the resonator length, and FIG. 6D represents changes of the laser oscillation frequency.

As illustrated in FIG. 6A to FIG. 6D, the movable mirror was driven to cover the positions between z2 and z3 where the laser oscillation was allowed by the light source. Specifically, the movable mirror was driven from the position z5 where the shortest resonator length was attained to the position z6 where the longest resonator length was attained. Laser oscillation was not allowed while the movable mirror was between the positions z5 and z2 and between the positions z3 and z6.

A frequency of the reciprocating movement of the movable mirror was set to 300 kHz. The surface emitting laser light source was controlled as described below by using the control unit 104 and the laser driving circuit 103.

Specifically, while the movable mirror was moved in a direction to decrease the resonator length, that is, in the course of moving the movable mirror from the position z6 to the position z5, current application of the laser driving current started when the movable mirror passed the position z2.

Until the movable mirror had reached the position z5 where the shortest resonator length was attained and returned from there to the position z2, a driving current of 8 mA was continuously applied.

Subsequently, 6 mA current was continuously applied while the movable mirror was moved from the positions z2 to z3, and the current application stopped when the movable mirror had reached the position z3.

As a result, the sweeping over a wide band of 30 THz was realized at a half-value width of wavelength (Of in FIG. 6D).

In this example, since the frequency of the reciprocating movement of the movable mirror, that is, the wavelength sweeping frequency, was set to a high speed of 300 kHz, the preliminary current injection time when no laser oscillation occurred even when the driving current was injected was made shorter to 500 ns.

To realize a wide band sweeping even with a short preliminary current injection time, therefore, the amount of preliminary current injection was increased. By appropriately increasing the amount of the preliminary current injection as in this example, it is possible, even in the high speed wavelength sweeping, to provide the effect of the present invention and realize a wide band wavelength sweeping.

### Example 3

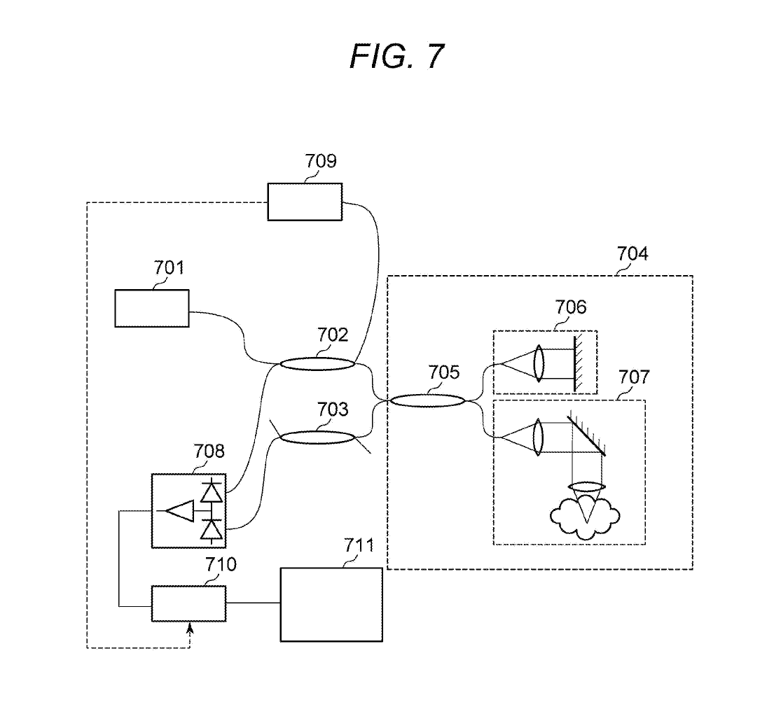

As Example 3, an exemplary structure of an image acquiring apparatus (specifically an OCT apparatus) including, as a light source unit, the light source apparatus according to the embodiment of the present invention will be described by referring to FIG. 7.

In FIG. 7, a light source apparatus 701 according to this example and an OCT interferometer 704 are provided. A scanning unit 707 of a sample and a reference surface 706 are also provided.

A fiber coupler 705 combines light flux from a sample and a reference surface, respectively, to generate interference light. A differential detection system is formed by fiber couplers 702, 703, and a modulated interference signal is differentially detected by a differential detector 708.

A k-clock device 709 generates a frequency clock used to calculate tomographic images. A computer 710 digitizes an electrically detected signal and performs calculations such as Fourier transformation on the digitized signal to provide a tomographic image which is displayed by a display device 711.

Light flux from the light source apparatus 701 passes through the fiber and branches into two directions by the coupler 702. One of the branched light fluxes is connected to the k-clock device 709 where a frequency clock is generated. The other of the branched light fluxes branches again into two directions by the coupler 705.

One arm of the branched light fluxes irradiates a retina which is a sample at an eyeground via a scanning optical system. The reflected light from the retina returns to the fiber coupler 705. The other arm of the branched light fluxes irradiates a reference mirror, and the reflected light from the reference mirror returns to the fiber coupler 705 again.

Thus, the reflected light transmitted from the sample measuring unit and the reflected light transmitted from the reference unit are interfered at the fiber coupler 705 (interference unit) to provide interference light which then proceeds via the couplers 702, 703 to enter the differential detector 708 formed as an optical detecting unit.

At this time, the wavelength from the light source apparatus 701 is changed to obtain a modulated interference signal according to a configuration of tomography.

This signal is then digitized in synchronism with the frequency clock generated in the k-clock device 709 and subjected to Fourier transformation in the computer 710 formed as an image processor, to thereby obtain a tomography signal.

Since this is only a point tomography signal, a one-dimensional tomographic image is measured by scanning by the scanning unit 707 and visualized by the display device 711 to detect an optical tomographic image.

Thus, an optical tomographic image acquiring apparatus is provided in this manner and an optical tomographic image calculated by the wide band interference signal having a long coherence length and a frequency sweeping width of 30 THz or more can be obtained. Accordingly, an OCT apparatus having a large detection depth and high detection resolution in the depth direction can be provided.

As described above, by using the surface emitting type and reciprocatingly-swept type light source according to the embodiment of the present invention in the OCT apparatus, it is possible to take a high quality tomographic image having a superior S/N ratio.

According to the embodiment of the present invention, the light source apparatus including a surface emitting laser capable of restricting the influence of temperature change while performing a wide band sweeping, and a method for driving such a surface emitting laser can be realized.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-169739, filed Aug. 19, 2013, and Japanese Patent Application No. 2014-131616, filed Jun. 26, 2014, which are hereby incorporated by reference herein in their entirety.

What is claimed is:

1. A light source apparatus comprising:
a surface emitting laser including a movable mirror, a mirror arranged opposite to the movable mirror, and an active layer arranged between the two mirrors;
a mirror driving unit configured to move the movable mirror to a position where laser oscillation is not performed;
a laser driving unit configured to inject current into the surface emitting laser;
a storage unit configured to store position information of the movable mirror, the position information including a mirror position where laser oscillation is not performed and a mirror position where laser oscillation is performed; and
a control unit configured to control the laser driving unit and to determine start timing of the current injection into the surface emitting laser according to the position information output from the storage unit.

2. The light source apparatus according to claim 1, wherein
the laser driving unit is configured to start the current injection into the surface emitting laser after the movable mirror has moved to a position where a wavelength with no light emitting gain becomes a resonant wavelength of the surface emitting laser, and
before the movable mirror is moved to a position where a wavelength with light emitting gain becomes the resonant wavelength of the surface emitting laser.

3. The light source apparatus according to claim 1, wherein
the laser driving unit is configured to start the current injection into the surface emitting laser at least 500 ns before the movable mirror is moved to reach a position where laser oscillation is allowed.

4. The light source apparatus according to claim 1, wherein
the laser driving unit is configured to start the current injection into the surface emitting laser at least 1 μs before the movable mirror is moved to reach a position where laser oscillation is allowed.

5. The light source apparatus according to claim 2, wherein
the laser driving unit is configured to inject the current into the surface emitting laser so that the current injected into the surface emitting laser before the movable mirror is moved to reach the position where the wavelength with the light emitting gain becomes the resonant wavelength is larger than the current injected into the surface emitting laser to perform laser oscillation after the movable mirror has moved to the position where the wavelength with the light emitting gain becomes the resonant wavelength.

6. The light source apparatus according to claim 1, wherein
after the current injection into the surface emitting laser has started,
the laser driving unit is configured to stop the current injection into the surface emitting laser after the movable mirror has been moved to the position where a wavelength with no light emitting gain becomes a resonant wavelength of the surface emitting laser, and before the movable mirror is moved to the position where the wavelength with the light emitting gain becomes the resonant wavelength of the surface emitting laser.

7. The light source apparatus according to claim 1, further comprising:
a signal source, wherein
the control unit is configured to synchronize with an output of the signal source to generate a movable mirror drive signal by which the output of the surface emitting laser changes in a nearly linear manner relative to a frequency.

8. The light source apparatus according to claim 1, wherein
the control unit is configured to control wavelength sweeping from a short wavelength to a long wavelength.

9. A method for driving a surface emitting laser including a movable mirror, a mirror arranged opposite to the movable mirror, and an active layer arranged between the two mirrors, comprising:
starting current injection into the surface emitting laser after the movable mirror has moved to a position where a wavelength with no light emitting gain becomes a resonant wavelength of the surface emitting laser, and
before the movable mirror is moved to a position where a wavelength with light emitting gain becomes the resonant wavelength of the surface emitting laser.

10. The method for driving a surface emitting laser according to claim 9, wherein
the starting the current injection into the surface emitting laser is at least 500 ns before the movable mirror is moved to reach a position where laser oscillation is allowed.

11. The method for driving a surface emitting laser according to claim 9, wherein
the starting the current injection into the surface emitting laser is at least 1 μs before the movable mirror is moved to reach a position where laser oscillation is allowed.

12. The method for driving a surface emitting laser according to claim 9, wherein
the current injection into the surface emitting laser before the movable mirror is moved to reach the position where the wavelength with the light emitting gain becomes the resonant wavelength is larger than the current injection into the surface emitting laser to perform laser oscillation after the movable mirror has moved to the position where the wavelength with the light emitting gain becomes the resonant frequency.

13. The method for driving a surface emitting laser according to claim 9, further comprising:
after the starting the current injection into the surface emitting laser,
stopping the current injection into the surface emitting laser after the movable mirror has been moved to the position where the wavelength with the light emitting gain becomes the resonant wavelength of the surface emitting laser, and before the movable mirror is moved to the position where the wavelength with the light emitting gain becomes the resonant wavelength of the surface emitting laser.

14. The method for driving a surface emitting laser according to claim 9, further comprising:
generating a movable mirror drive signal by which the output of the surface emitting laser changes in a nearly linear manner relative to a frequency.

15. The method for driving a surface emitting laser according to claim 9, further comprising:
sweeping the wavelength from a short wavelength to a long wavelength by the control of the control unit.

16. An image acquiring apparatus, comprising:
the light source apparatus according to claim 1,
a measuring unit configured to irradiate a sample with light from the light source apparatus and transmit reflected light from the sample;
a reference unit configured to irradiate a reference mirror with light from the light source apparatus and transmit the reflected light from the reference mirror;
an interference unit configured to interfere the reflected light from the sample measuring unit with the reflected light from the reference unit;
an optical detecting unit configured to detect interference light from the interference unit; and
an image processing unit configured to acquire an optical tomographic image of the sample according to the light detected by the optical detecting unit.
